(19) United States
(12) Patent Application Publication
(10) Pub. No.: US 2007/0160915 A1
(43) Pub. Date: Jul. 12, 2007

(54) Phase shifting mask having a calibration feature and method therefor

(76) Inventors: James J. Willard, Round Rock, TX (US); Patsy E. Bergman, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/328,775

(22) Filed: Jan. 10, 2006

(51) Int. Cl. G03C 5/00; G03F 9/00; G03F 1/00

(52) U.S. Cl. 430/5; 430/22; 430/30

(57) ABSTRACT

A phase shift mask that corresponds to a layer of at least one semiconductor die has a substrate. A method thereof includes overlying a phase shifter film over the substrate. A permanent light calibration feature is positioned in close proximity to the at least one semiconductor die. The permanent light calibration feature has a predetermined area defined by an opening in the phase shifter film overlying the substrate. The predetermined area is within a range of area values and has a value that provides a light calibration value for use in testing with light for defects in the phase shift mask. An identification feature is positioned in close proximity to the permanent light calibration feature and is substantially larger than each of the permanent light calibration features. The identification feature provides a reference point to assist in locating a corresponding permanent light calibration feature.

### FIELD OF THE INVENTION

This invention relates to phase shifting masks, and more particularly to a light calibration feature on the phase shifting mask.

### BACKGROUND OF THE INVENTION

Semiconductor integrated circuits have many thousands of devices interconnected on a single chip. The trend has been, and is continuing to be, to pack more and more transistors onto a single chip. This requires the individual interconnect components to be fabricated at greatly reduced dimensions. The current dimensions are 65 nm or even 45 nm with 180 nm and 130 nm being commonplace. In order to accomplish this, the process by which the patterns are transferred from the photomask to the wafer becomes increasingly more complex.

Photolithography and the use of photolithographic reticles is the key to producing these complex patterns. In the photolithographic process a photoresist layer is deposited on a wafer and a form of radiant energy is directed toward and through a reticle or photomask to selectively expose the resist into the desired pattern. After the exposed resist is developed by well known processes, an etch process is then used to define the required circuit or pattern on the wafer. Multiple layers are built in such a manner resulting in the final IC.

One method that is becoming widely used for the photolithographic process is phase shifting lithography. The use of phase shifting masks (PSM) has allowed features as small as 0.10 μm to be resolved during the lithographic process. In this process, a transparent substrate, usually quartz, is patterned with an opaque material to form the desired circuit or pattern. The opaque material that is widely used is chrome. Phase shifting material is then deposited and patterned to be either in between the chrome features or overlying the features or both. The manufacture of the circuitry and patterns is widely known and is not repeated herein.

However, the use of phase shifting masks is not without issues. One of the primary detractions is that the masks are known to have high levels of defectivity associated with them from the processes used to manufacture them. These defects can arise from a variety of circumstances that can include, but are not limited to, common pinholes in either the chrome or the phase shifting material, excess opaque material outside of the desired circuit pattern, particulate contaminants, and others. These defects are critical in the wafer manufacturing process and need to be repaired or cleaned prior to the use of the photomask in production. In addition, any defectivity that results from the use of the photomask in production would need to be detected so that die yield remains constant. The key to the repair or removal of these defects involves the detection of them.

If defects are allowed to stay on the photomask, erroneous circuit or test patterns will be produced on the wafer. The key to detecting these defects is by the use of a photomask inspection tool. Automated mask inspection tools have been in use for many years and the description of these will not be undertaken. A good description of the detection methodology as well as tool configurations can be found in either U.S. Pat. No. 5,717,204, entitled “Inspecting Optical Masks with Electron Beam Microscopy, assigned to KLA Instruments Corporation or in U.S. Pat. No. 6,836,560 entitled “Advanced Phase Shift Inspection Method”, assigned to KLA-Tencor Technologies Corporation.

These inspection tools can require lengthy set-up times and can be difficult to use. One issue that arises is during the calibration of the light source used for the inspection. The light that is illuminated for either transmission or reflection purposes needs to be calibrated.

This is because of the variation in the photomask itself relative to the opaque material coverage, the die size, the phase shifting material coverage and such. At present, users of defect inspection tools can either calibrate the light on existing patterns that reside on the photomask, such as mask identification keys, or can use calibration marks that are used for other lithographic purposes, such as alignment keys and such. Use of mask identification keys would not be standardized from mask set to mask set and may not allow for a very sensitive detection of defects. Further, use of alignment keys or such, is time consuming as the keys can be difficult to find for the average user.

A need therefore exists to reduce the inspection time for the phase shifting photomasks as well as make the process more standardized. This can be done by adding a light calibration feature, or multiple features, in a known location on a photomask while having a known descriptor in the area to aid in identification.

### BRIEF DESCRIPTION OF THE DRAWINGS

The foregoing and further and more specific objects and advantages of the invention will become readily apparent to those skilled in the art from the following detailed description of a preferred embodiment thereof taken in conjunction with the following drawings:

FIG. 1 is an overview of a phase shifting mask showing multiple die according to one embodiment;

FIG. 2 is a higher magnification showing the light calibration feature located within the scribe grids of the array; and

FIG. 3 is a cross section of a phase shifting mask showing the substrate with overlying phase shifting film and a dimension of the light calibration feature.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE INVENTION

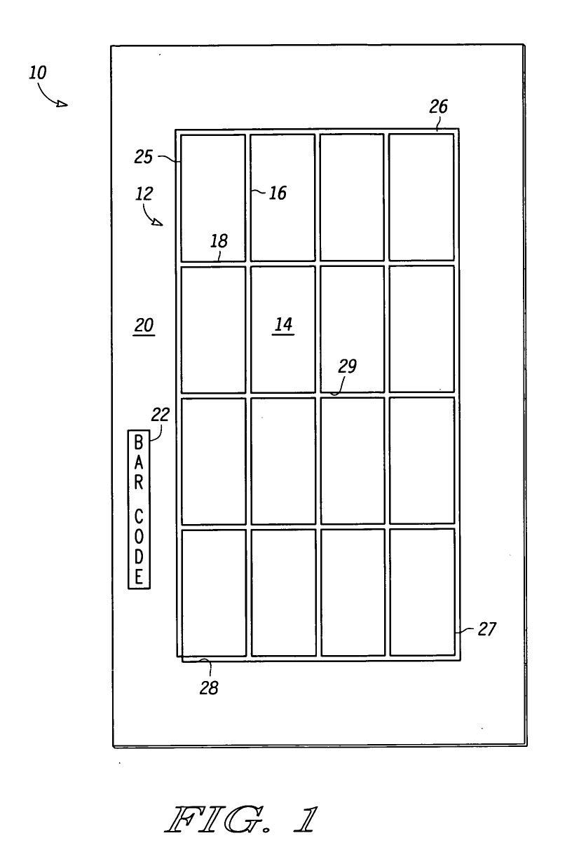

An embodiment of the present invention is given with reference to the accompanying drawings. Reference is given to FIG. 1 where a reticle or phase shift mask 10 is shown. An array 12 of rows and columns of individual die 14 is patterned on the phase shift mask 10. One of skill would recognize that any number of die 14 could be within the array 12 while maintaining the spirit of the present invention. In the current embodiment, the array 12 is a 4×4 array of die. The die are separated from one another by scribe lines, illustrated in FIG. 1 as vertical scribe lines 16 and horizontal scribe lines 18. Also illustrated in FIG. 1 is the fiducial area 20 which is in the periphery of the array and contains the alignment marks specific to the stepper as well as the phase shift mask barcode 22 and any other structures necessary to identify the phase shift mask.

Scribe lines are generally used for alignment marks and other test patterns. In the illustrated form the scribe lines also contain light calibration key areas 25, 26, 27, 28 and 29. Light calibration key areas 25, 26, 27 and 28 are located along the edge of the array while light calibration key area 29 is located in close proximity to the center of the array. It is noted that in an array that is, for instance, a 5×5 array of die, the center of the array would be located in the center of a die. It is preferred that the light calibration key be placed in the scribe lines and not be placed within the die area. It is a preferred embodiment that where the center of the array is within a die, that the light calibration key be located as near to the center as possible but within a scribe line.

The light calibration keys are preferably located in multiple sites across the phase shift mask field. This has several benefits. One of these benefits is that it is known that the phase shift mask surfaces have variations in the transmission levels and actinic properties which can result in issues arising during the phase shift mask inspection. For instance, a false detection of a defect can result due to these variations. The use of multiple sites allows the user to re-calibrate the light transmission for various die and therefore reduce the likelihood of any false detections.

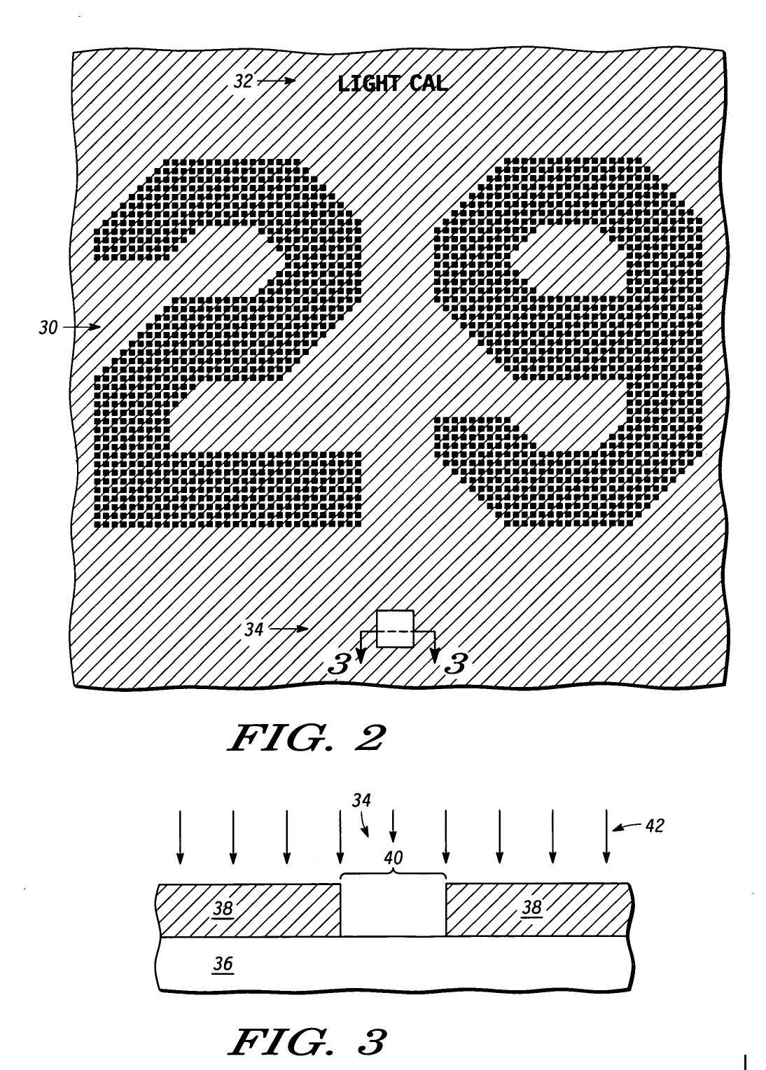

Reference is now given to FIG. 2 which is a higher magnification of the light calibration key area. In order for the light calibration key to be found, a large identification feature 30 can be placed in the vicinity of the light calibration key. This will allow any user to readily locate the light calibration key. This identification feature could also serve to identify the particular layer that is being exposed with the phase shift mask 10. While it is preferred that an identification feature be present and also serve to identify the phase shift mask 10, any feature would be within the scope of the present invention.

A key title 32 can be located in the vicinity of the large identification feature 30. The key title 32 is present to allow a user to quickly identify what the structure is that is located nearby. The key title 32 is optional and can be left off of the phase shift mask 10.

It is preferred that the light calibration key 34 is located in close proximity to the large identification feature 30 or in an area that is known to the user. One of the advantages of using this light calibration key 34 is that the speed with which the defectivity scans can be performed. Taking time to search for the light calibration key 34 is counter to this benefit.

The light calibration key 34 is a permanent feature and therefore can be used for initial inspections at the mask shop, as well as for inspections in the chip manufacturing facility. In many chip manufacturing facilities the phase shift mask 10 is inspected for defects when it first arrives or prior to the first use, as well as after a number of uses. In one form the phase shift mask 10 is inspected for defects after fifteen to twenty uses. The use of a readily recognizable and easily locatable light calibration key 34 will significantly reduce the amount of time that this re-inspection takes to perform.

In a preferred form the size of the light calibration key 34 is 8 μm by 8 μm for 0.25 pixel size and smaller. A larger key would be necessary for larger pixel sizes. Although 8 μm by 8 μm features violate most ground rule limits, it was found that since the light calibration key 34 was placed away from the active circuitry, the process issues were minimized.

Reference is now given to FIG. 3 which illustrates a cross-section of a phase shift mask with a light calibration key. The cross-sectional area is shown as line 3-3 in FIG. 2.

Returning again to FIG. 3, a clear region 36, such as quartz, has a layer 38 deposited and patterned above it. In one form layer 38 is a semi-opaque or semi-dark film, also known as a phase shifter film. This film may be molybdenum silicide (MoSi), chromium fluoride (CrF) or zirconium-type materials such as ZrSiO or the like. The phase shifter film is patterned to form an 8 μm by 8 μm box, shown as opening 40 in the current cross-section that is to be used as the light calibration key feature. While not illustrated, other areas that have the circuitry patterns would also have areas of an opaque material, usually chrome. Other layers of material are also contemplated and would fall within the scope of the present invention.

When the phase shift mask of FIG. 3 is used for defect inspection, light 42 is directed towards and through the opening 40 to obtain a transmitted light calibration value. One of skill would recognize that in operation, some defect inspection tools would also detect the light transmission values around the edges of the opening including a small amount of the phase shifting material. This would most closely resemble the actual inspection of structures and the corresponding edges of such.

The inspection tool can be operated in any mode that requires use of a transmitted light value to detect defects on or in a phase shift mask. For instance, die-to-die or die-to-database are also contemplated.

By now it should be appreciated that there has been provided an enhanced phase shift mask that has applicability to phase shift mask plate production and which can be implemented in high-volume photomask shops. The size and placement of the features described herein abide by established production rules so as to not negatively affect wafer processing.

In one form there is herein provided a phase shift mask for use in forming a layer of at least one semiconductor die. The phase shift mask has a substrate and a phase shifter film overlying the substrate. A permanent light calibration feature is positioned in close proximity to the at least one semiconductor die. The permanent light calibration feature has a predetermined area defined by an opening in the phase shifter film overlying the substrate. The predetermined area is within a range of area values and having a value that provides a light calibration value for use in testing with light for defects on the phase shift mask. In one form the phase shift mask further has a plurality of permanent light calibration features positioned around a periphery of the layer of the at least one semiconductor die. Each of the plurality of permanent light calibration features provides a respective light calibration value for use in testing with light for defects in a respective separate portion of the phase shift mask. In another form the phase shift mask is used to form a plurality of semiconductor die arranged in an array, the array comprising a plurality of scribe lines, the permanent light calibration feature being located within one of the plurality of scribe lines. In one form the phase shift mask further has a plurality of semiconductor die arranged in a rectangular array, positioned on the substrate of the phase shift mask and separated by scribe lines. A plurality of permanent light calibration features is positioned within a plurality of the scribe lines, the plurality of permanent light calibration features being positioned in close proximity to each corner of the rectangular array. In an alternate form the plurality of permanent light calibration features further includes an additional permanent light calibration feature positioned within an inner scribe line of the array and substantially within a central area of the array. In yet another form the phase shift mask further includes an identification feature positioned in close proximity to and substantially larger than the permanent light calibration feature, the identification feature providing a reference point to assist in locating the permanent light calibration feature. In another form the identification feature further includes a plurality of closely positioned vias in the phase shifter film that are filled with a predetermined material.

There is also provided a method of providing a phase shift mask for use in forming a layer of at least one semiconductor die. A substrate of the phase shift mask is provided and a phase shifter film overlies the substrate. A permanent light calibration feature is positioned in close proximity to the at least one semiconductor die, the permanent light calibration feature having a predetermined area defined by an opening in the phase shifter film overlying the substrate, the predetermined area being within a range of area values and having a value that provides a light calibration value for use in testing with light for defects in the phase shift mask. In one form a plurality of permanent light calibration features is provided around a periphery of the layer of the at least one semiconductor die. Each of the plurality of permanent light calibration features provides a respective light calibration value for use in testing with light for defects in a respective separate portion of the phase shift mask. In one form the phase shift mask is used to form a layer of a plurality of semiconductor die arranged in an array. The array is formed with a plurality of scribe lines, and the permanent light calibration feature is located within one of the plurality of scribe lines. In another form the phase shift mask is used to form a layer of a plurality of semiconductor die arranged in a rectangular array. The layer is positioned overlying the substrate of the phase shift mask and separated by scribe lines. A plurality of permanent light calibration features are positioned within a plurality of the scribe lines and in close proximity to each corner of the rectangular array. In another form an additional permanent light calibration feature is positioned within an inner scribe line of the rectangular array and substantially within a central area of the rectangular array. In yet another form an identification feature is positioned in close proximity to and is substantially larger than the permanent light calibration feature. The identification feature provides a reference point to assist in locating the identification feature. In another form the identification feature is formed with a plurality of closely positioned vias in the phase shifter film and filling the plurality of closely positioned vias with a predetermined material.

In yet another form there is provided a phase shift mask for use in forming a layer of a plurality of semiconductor die arranged in an array. The phase shift mask has a substrate of transparent material. A phase shifter film overlies the substrate. A plurality of permanent light calibration features is positioned in at least two quadrants of the phase shift mask. Each of the plurality of permanent light calibration features has a predetermined area defined by a respective opening in the phase shifter film. The predetermined area is within a range of area values and has a value that provides a light calibration value when exposed to light. The light calibration value is used to test the phase shift mask for defects. In yet another form the phase shift mask is rectangular and the plurality of permanent light calibration features are in at least each corner region of the phase shift mask and there is at least one in a central region of the phase shift mask.

In one form the plurality of semiconductor die in the array are separated by a plurality of scribe lines and each of the plurality of permanent light calibration features is positioned within the plurality of scribe lines. In another form each of the plurality of permanent light calibration features has an identification feature positioned in close proximity and is substantially larger than each of the plurality of permanent light calibration features. Each identification feature provides a reference point to assist in locating a corresponding permanent light calibration feature. In another form each identification feature has a plurality of closely positioned vias in the phase shifter film that are filled with a predetermined material. In yet another form each of the plurality of permanent light calibration features is a square opening in the phase shifter film.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

What is claimed is:

1. A phase shift mask for use in forming a layer of at least one semiconductor die, comprising:
a substrate;
a phase shifter film overlying the substrate; and
a permanent light calibration feature positioned in close proximity to the at least one semiconductor die, the permanent light calibration feature having a predetermined area defined by an opening in the phase shifter film overlying the substrate, the predetermined area being within a range of area values and having a value that provides a light calibration value for use in testing with light for defects on the phase shift mask.

2. The phase shift mask of claim 1 further comprising:
a plurality of permanent light calibration features positioned around a periphery of the phase shifter film of the at least one semiconductor die, each of the plurality of permanent light calibration features providing a respective light calibration value for use in testing with light for defects in a respective separate portion of the phase shift mask.

3. The phase shift mask of claim 1 wherein the phase shift mask is further used to form a plurality of semiconductor die arranged in an array, the array comprising a plurality of scribe lines, the permanent light calibration feature being located within one of the plurality of scribe lines.

4. The phase shift mask of claim 1 wherein the at least one semiconductor die further comprises:
a plurality of semiconductor die arranged in a rectangular array, positioned on the substrate of the phase shift mask and separated by scribe lines; and
a plurality of permanent light calibration features positioned within a plurality of the scribe lines, the plurality of permanent light calibration features being positioned in close proximity to each corner of the rectangular array.

5. The phase shift mask of claim 4 wherein the plurality of permanent light calibration features further comprises an additional permanent light calibration feature positioned within an inner scribe line of the array and substantially within a central area of the array.

6. The phase shift mask of claim 1 further comprising:
an identification feature positioned in close proximity to and substantially larger than the permanent light calibration feature, the identification feature providing a reference point to assist in locating the permanent light calibration feature.

7. The phase shift mask of claim 6 wherein the identification feature further comprises a plurality of closely positioned vias in the phase shifter film that are filled with a predetermined material.

8. A method of providing a phase shift mask for use in forming a layer of at least one semiconductor die comprising:
providing a substrate of the phase shift mask;
providing a phase shifter film overlying the substrate; and
positioning a permanent light calibration feature in close proximity to the at least one semiconductor die, the permanent light calibration feature having a predetermined area defined by an opening in the phase shifter film overlying the substrate, the predetermined area being within a range of area values and having a value that provides a light calibration value for use in testing with light for defects in the phase shift mask.

9. The method of claim 8 further comprising:
positioning a plurality of permanent light calibration features around a periphery of the layer of the at least one semiconductor die, each of the plurality of permanent light calibration features providing a respective light calibration value for use in testing with light for defects in a respective separate portion of the phase shift mask.

10. The method of claim 8 further comprising:
using the phase shift mask to form a layer of a plurality of semiconductor die arranged in an array, forming the array with a plurality of scribe lines, and locating the permanent light calibration feature within one of the plurality of scribe lines.

11. The method of claim 8 further comprising:
using the phase shift mask to form a layer of a plurality of semiconductor die arranged in a rectangular array, the layer positioned overlying the substrate of the phase shift mask and separated by scribe lines; and
providing a plurality of permanent light calibration features positioned within a plurality of the scribe lines, the plurality of permanent light calibration features being positioned in close proximity to each corner of the rectangular array.

12. The method of claim 11 further comprising providing an additional permanent light calibration feature positioned within an inner scribe line of the rectangular array and substantially within a central area of the rectangular array.

13. The method of claim 8 further comprising:
positioning an identification feature in close proximity to and being substantially larger than the permanent light calibration feature, the identification feature providing a reference point to assist in locating the identification feature.

14. The method of claim 13 further comprising forming the identification feature with a plurality of closely positioned vias in the phase shifter film and filling the plurality of closely positioned vias with a predetermined material.

15. A phase shift mask for use in forming a layer of a plurality of semiconductor die arranged in an array, comprising:
a substrate of transparent material;
a phase shifter film overlying the substrate; and
a plurality of permanent light calibration features positioned in at least two quadrants of the phase shift mask, each of the plurality of permanent light calibration features having a predetermined area defined by a respective opening in the phase shifter film, the predetermined area being within a range of area values and having a value that provides a light calibration value when exposed to light, the light calibration value being used to test the phase shift mask for defects.

16. The phase shift mask of claim 15 wherein the phase shift mask is rectangular and the plurality of permanent light calibration features comprise at least one in each corner region of the phase shift mask and at least one in a central region of the phase shift mask.

17. The phase shift mask of claim 16 wherein the plurality of semiconductor die in the array are separated by a plurality of scribe lines and each of the plurality of permanent light calibration features is positioned within the plurality of scribe lines.

18. The phase shift mask of claim 17 wherein each of the plurality of permanent light calibration features further comprises an identification feature positioned in close proximity and being substantially larger than each of the plurality of permanent light calibration features, each identification feature providing a reference point to assist in locating a corresponding permanent light calibration feature.

19. The phase shift mask of claim 18 wherein each identification feature further comprises a plurality of closely positioned vias in the phase shifter film that are filled with a predetermined material.

20. The phase shift mask of claim 18 wherein each of the plurality of permanent light calibration features is a square opening in the phase shifter film.
